(19) United States
(12) Patent Application Publication
(10) Pub. No.: US 2024/0333276 A1
(43) Pub. Date: Oct. 3, 2024

(54) RADIO FREQUENCY SWITCH AND SWITCH CONTROL CIRCUIT THEREOF

(71) Applicant: Samsung Electro-Mechanics Co., Ltd., Suwon-si (KR)

(72) Inventors: Byeonghak JO, Suwon-si (KR); Wonsun HWANG, Suwon-si (KR); Shinhaeng HEO, Suwon-si (KR); Dongil KANG, Suwon-si (KR)

(73) Assignee: Samsung Electro-Mechanics Co., Ltd., Suwon-si (KR)

(21) Appl. No.: 18/505,628

(22) Filed: Nov. 9, 2023

(30) Foreign Application Priority Data
Mar. 30, 2023 (KR) 10-2023-0041943

(51) Int. Cl. H03K 17/0412

(52) U.S. Cl. CPC H03K 17/04123

(57) ABSTRACT

A switch control circuit that is configured to transmit a turn-on voltage and a turn-off voltage through an output terminal to control a switch is provided. The switch control circuit includes a first transistor configured to be turned on in response to a first voltage level of a first control signal and output the turn-on voltage; a second transistor configured to be turned on in response to a second voltage level of the first control signal and output the turn-off voltage; a resistor connected between a power supply and the output terminal; and a capacitor connected between the output terminal and a ground, where the power supply is configured to supply the turn-on voltage of the switch.

### CROSS-REFERENCE TO RELATED APPLICATIONS

This application claims the benefit under 35 USC § 119 (a) of Korean Patent Application No. 10-2023-0041943 filed on Mar. 30, 2023, in the Korean Intellectual Property Office, the entire disclosure of which is incorporated herein by reference for all purposes.

### BACKGROUND

### 1. Field

The following description relates to a radio frequency (RF) switch and a switch control circuit thereof.

### 2. Description of Related Art

As the implementation of 5G networks in wireless communication systems increases, a Long-Term Evolution (LTE) network, a 2G network, and a 5G network are being integrated into a single mobile system. As a result, as various components may be integrated in a limited space, the number of passive elements such as, but not limited to, inductors and capacitors that share a power supply and are connected to the power supply is decreasing.

Since many components may share power supply, it may be desirous to implement components that are sensitive to power supply noise with a robust structure to counter the effect of power supply noise. In particular, since a radio frequency (RF) switch that switches transmission and reception signals may be connected to a reception terminal, reception sensitivity may be degraded due to power supply noise flowing from the power supply while it is turned on.

To reduce this power supply noise, the RF switch may use a low drop-out (LDO) circuit or resistor-capacitor (RC) filter. The RC filter may be connected to an output of the switch control circuit that controls the switch transistors constituting the RF switch, and may be composed of a resistor and a capacitor. When using an LDO circuit, power supply noise may be reduced as much as the power supply rejection ratio (PSRR) of the LDO circuit. However, in order to reduce power consumption, the power supply used in the wireless communication system may be lowered and the power supply used to drive the switch transistor is increased. Therefore, performance may be deteriorated when an LDO circuit is used, and the chip size may also increase. Additionally, when using an RC filter, power supply noise can be removed. However, switching time of switch transistors due to resistors and capacitors increases.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, a switch control circuit is configured to transmit a turn-on voltage and a turn-off voltage through an output terminal to control a switch, the switch control circuit includes a first transistor configured to be turned on in response to a first control signal being at a first voltage level, and output the turn-on voltage; a second transistor configured to be turned on in response to the first control signal being at a second voltage level, and output the turn-off voltage; a resistor connected between a power supply and the output terminal; and a capacitor connected between the output terminal and a ground, wherein the power supply is configured to supply the turn-on voltage of the switch.

The switch control circuit may further include a third transistor connected in parallel with the resistor and configured to be turned on for a first period from a first time point when the first control signal is changed from the second voltage level to the first voltage level.

The switch control circuit may further include a pulse generator configured to generate a second control signal to turn on the third transistor during the first period from the first time point.

The first period may be a portion of a period in which the first transistor is turned on.

The pulse generator may include a first inverter configured to receive the first control signal, and delay and output the first control signal by a set time; a second inverter configured to delay and output the output signal of the first inverter by a set time; and a logic element configured to generate the second control signal based on an output signal of the first inverter and an output signal of the second inverter.

The logic element may be an AND gate.

The switch control circuit may include a fourth transistor connected between the first transistor and the output terminal, wherein the fourth transistor has a control terminal connected to a ground terminal, and is configured to be turned on when the first transistor is turned on; and a fifth transistor connected between the second transistor and the output terminal, wherein the fifth transistor has a control terminal connected to the ground terminal, and is configured to be turned on when the second transistor is turned on.

The resistor may be connected to any one of between the power supply and the first transistor, between the first transistor and the fourth transistor, and between the fourth transistor and the output terminal.

In a general aspect, a radio frequency (RF) switch includes a switch connected between a first port and a second port; and a switch control circuit configured to output a turn-on voltage corresponding to a first voltage level of a first control signal to the switch through an output terminal of the switch control circuit, and configured to output a turn-off voltage corresponding to a second voltage level of the first control signal to the switch through the output terminal of the switch control circuit, wherein the switch control circuit includes a first transistor configured to provide the turn-on voltage to the output terminal; a second transistor configured to provide the turn-off voltage to the output terminal; a resistor connected between a power supply which transmits the turn-on voltage and the output terminal; and a capacitor connected between the output terminal and a ground.

The switch control circuit may further include a third transistor connected in parallel with the resistor, and configured to be turned on during a second period from a first time point when the first control signal is changed from the second voltage level to the first voltage level among a first period when the first transistor is turned on.

The switch control circuit may further include a pulse generator configured to generate a second control signal to turn on the third transistor during the second period from the first time point, and output the second control signal to a control terminal of the third transistor.

The pulse generator may be configured to generate the second control signal based on the first control signal.

The switch control circuit may further include a fourth transistor connected between the first transistor and the output terminal, wherein the fourth transistor has a control terminal connected to the ground, and is configured to be turned on when the first transistor is turned on; and a fifth transistor connected between the second transistor and the output terminal, wherein the fifth transistor has a control terminal connected to the ground, and is configured to be turned on when the second transistor is turned on.

The resistor may be connected to any one of between the power supply and the first transistor, between the first transistor and the fourth transistor, and between the fourth transistor and the output terminal.

In a general aspect, a radio frequency (RF) switch, includes a switch control circuit, comprising a gate control signal generator configured to generate a gate control signal; wherein the gate control signal generator includes a first transistor connected between a first power supply and an output terminal, and configured to receive a positive voltage from the power supply; a second transistor connected between the output terminal and a second power supply, and configured to receive a negative voltage; a resistor connected between the power supply and the first transistor, and a third transistor connected in parallel with the resistor, and configured to be turned on or turned off based on a control signal output from a pulse generator.

A first end of the resistor may be connected to a source terminal of the third transistor, and a second end of the resistor may be connected to a drain terminal of the third transistor.

The third transistor may be turned on when the control signal is at a low voltage level, and may be turned off when the control signal is at a high voltage level.

Other features and examples will be apparent from the following detailed description, the drawings, and the claims.

### BRIEF DESCRIPTION OF DRAWINGS

FIG. 1 illustrates an example RF switch, in accordance with one or more embodiments.

FIG. 2 illustrates an example series switch S1 shown in FIG. 1.

FIG. 3 illustrates an example switch control circuit 130, in accordance with one or more embodiments.

FIG. 4 is a circuit diagram illustrating an example gate control signal generator 1312 shown in FIG. 3.

FIG. 5 illustrates operation timing of the example gate control signal generator 1312 shown in FIG. 4.

FIG. 6 is a circuit diagram illustrating an example pulse generator 1312_1 shown in FIG. 4.

FIG. 7, FIG. 8, and FIG. 9 are circuit diagrams illustrating another example of the gate control signal generator 1312 shown in FIG. 3.

FIG. 10 illustrates simulation results of the switching time of the gate control signal VG, in accordance with one or more embodiments.

FIG. 11 illustrates an example switch control circuit in a comparative example.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto. The use of the terms “example” or “embodiment” herein have a same meaning, e.g., the phrasing “in one example” has a same meaning as “in one embodiment”, and “one or more examples” has a same meaning as “in one or more embodiments.”

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Throughout the specification, when a component or element is described as being “on”, “connected to,” “coupled to,” or “joined to” another component, element, or layer it may be directly (e.g., in contact with the other component, element, or layer) “on”, “connected to,” “coupled to,” or “joined to” the other component, element, or layer or there may reasonably be one or more other components, elements, layers intervening therebetween. When a component, element, or layer is described as being “directly on”, “directly connected to,” “directly coupled to,” or “directly joined” to another component, element, or layer there can be no other components, elements, or layers intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

As used herein, the term “and/or” includes any one and any combination of any two or more of the associated listed items. The phrases “at least one of A, B, and C”, “at least one of A, B, or C”, and the like are intended to have disjunctive meanings, and these phrases “at least one of A, B, and C”, “at least one of A, B, or C”, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

One or more examples may provide an RF switch robust against power supply noise and a switch control circuit thereof.

Throughout the specification, an RF signal includes Wi-Fi (IEEE 802.11 family, etc.), WiMAX (IEEE 802.16 family, etc.), IEEE 802.20, long term evolution (LTE), Evolution-Data Optimized (Ev-DO), high-speed packet access plus (HSPA+), high-speed downlink packet access plus (HSDPA+), high-speed uplink packet access plus (HSUPA+), Enhanced Data GSM Evolution (EDGE), Global System for Mobile Communication (GSM), Global Positioning System (GPS), General Packet Radio Service (GPRS), Code Division Multiple Access (CDMA), Time Division Multiple Access (TDMA), digital enhanced cordless communication (DECT), Bluetooth, third generation (3G), fourth generation (4G), fifth generation (5G), and any other wireless and wired protocols designated thereafter, but is not limited thereto.

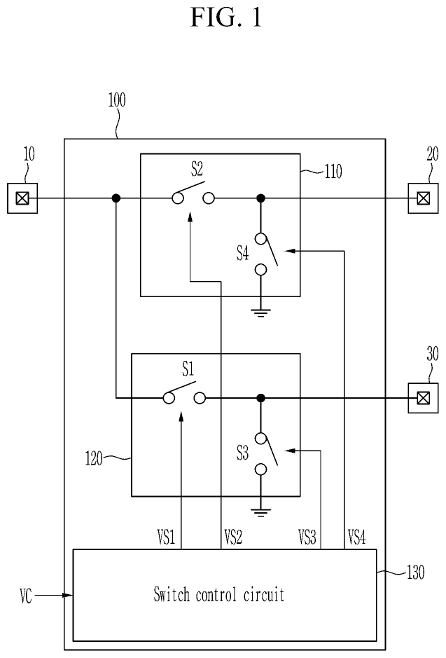

FIG. 1 illustrates an example RF switch, in accordance with one or more embodiments.

Referring to FIG. 1, the RF switch 100 may transmit an RF signal by connecting the antenna terminal 10 and the transmission terminal 20. Additionally, the RF switch 100 may receive an RF signal by connecting the antenna terminal 10 and the reception terminal 30.

The RF switch 100 may include a transmission switch 110, a reception switch 120, and a switch control circuit 130.

In an example, the transmission switch 110 may include a series switch S2 and a shunt switch S4. The series switch S2 may be connected between the antenna terminal 10 and the transmission terminal 20. The shunt switch S4 may be connected between the transmission terminal 20 and the ground. The series switch S2 and the shunt switch S4 may operate in a complementary manner. That is, when the series switch S2 is turned on, the shunt switch S4 may be turned off, and when the series switch S2 is turned off, the shunt switch S4 may be turned on.

The reception switch 120 may include a series switch S1 and a shunt switch S3. The series switch S1 may be connected between the antenna terminal 10 and the reception terminal 30. The shunt switch S3 may be connected between the reception terminal 30 and the ground. The series switch S1 and the shunt switch S3 may operate in a complementary manner. That is, when the series switch S1 is turned on, the shunt switch S3 may be turned off, and when the series switch S1 is turned off, the shunt switch S3 may be turned on.

The series switch S1, the series switch S2, the shunt switch S3, and the shunt switch S4 may be turned on or turned off according to the switch control signals VS1, VS2, VS3, and VS4 output from the switch control circuit 130.

When transmitting an RF signal, the series switch S2 may be turned on and the series switch S1 may be turned off. At this time, the shunt switch S4 may be turned off and the shunt switch S3 may be turned on.

When receiving an RF signal, the series switch S1 may be turned on and the series switch S2 may be turned off. At this time, the shunt switch S3 may be turned off and the shunt switch S4 may be turned on.

The switch control circuit 130 may receive a positive voltage VDD, a negative voltage VNEG, and a ground voltage VSS. In an example, the positive voltage VDD may be applied from an external power supply. In an example, the negative voltage VNEG may be a voltage generated from an external power source through a charge pump circuit.

Referring again to FIG. 1, the switch control circuit 130 may receive the control signal VC and may generate the switch control signals VS1, VS2, VS3, and VS4 using the positive voltage VDD, the negative voltage VNEG, and the ground voltage VSS based on the received control signal VC. The switch control circuit 130 may output the switch control signals VS1, VS2, VS3, and VS4 to the series switch S1, the series switch S2, the shunt switch S3, and the shunt switch S4, respectively.

In an example, unlike FIG. 1, the RF switch 100 may include only one of the transmission switch 110 and the reception switch 120. Additionally, the transmission switch 110 and the reception switch 120 may be composed of only a series switch S1 and a series switch S2, respectively, unlike FIG. 1.

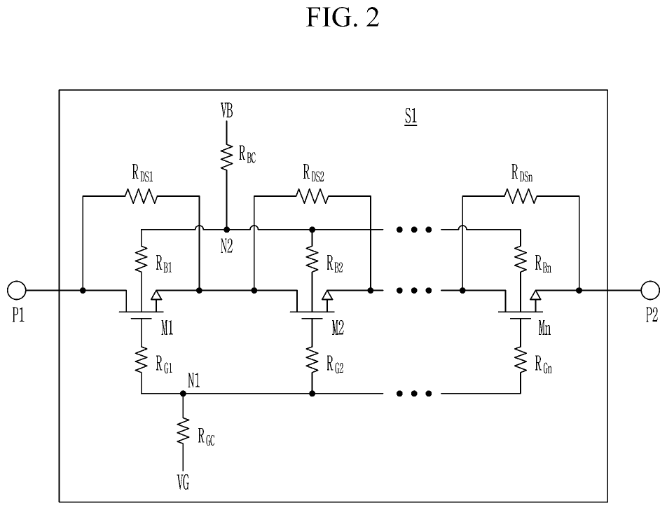

FIG. 2 illustrates an example series switch S1 shown in FIG. 1.

Referring to FIG. 2, the series switch S1 may be connected between a first port P1 and a second port P2. The first port P1 may be the antenna terminal 10, and the second port P2 may be the reception terminal 30. Although FIG. 2 shows the series switch S1 shown in FIG. 1, the series switch S2, shunt switch S3, and shunt switch S4 may also be configured identically or similarly to the series switch S1.

The series switch S1 may include at least one of transistors M1 to Mn connected in series between the first port P1 and the second port P2. When the transistors M1 to Mn are turned on, the first port P1 and the second port P2 may be connected to each other, and thus an RF signal may be received. When the transistors M1 to Mn are turned off, the first port P1 and the second port P2 are not connected to each other, and thus an RF signal may be blocked. The transistors M1 to Mn may be implemented with various types of transistors, such as, but not limited to, field effect transistors (FETs) and bipolar transistors that perform a switching operation. In FIG. 2, transistors M1 to Mn are shown as N type transistors. However, this is only an example, and the transistors M1 to Mn may be replaced with P type transistors. Hereinafter, for convenience of description, it is assumed that the transistors M1 to Mn are N-type FETs, but other transistors may be substituted.

Each transistor M1-Mn may have a gate terminal, a drain terminal, a source terminal, and a body terminal. In an example, the gate terminal may be a control terminal.

A drain terminal of the transistor M1 may be connected to the first port P1, and a source terminal of the transistor Mn may be connected to the second port P2. A source terminal of the transistor M1 may be connected to a drain terminal of the transistor M2, and a source terminal of the transistor M2 may be connected to a drain terminal of the transistor M3. In this manner, at least one transistor M1 to Mn may be connected in series between the first port P1 and the second port P2.

The gate terminal of each transistor M1 to Mn may be connected to a first end of each resistor R_{G1} to R_{Gn}, and the second end of each resistor R_{G1} to R_{Gn} may be connected to the common node N1. A first end of the resistor R_{GC} may be connected to the common node N1, and the gate control signal VG may be applied to the second end of the resistor R_{GC}. The gate control signal VG may have a positive (+) voltage (e.g., VDD in FIG. 1) as a turn-on voltage of the transistors M1 to Mn, and the gate control signal VG may have a negative (−) voltage (e.g., VNEG in FIG. 1) as a turn-off voltage of the transistors M1 to Mn. Alternatively, the gate control signal VG may have a ground voltage (e.g., VSS in FIG. 1) as a turn-off voltage of the transistors M1 to Mn. In the following description, it is assumed that the turn-off voltage of the transistors M1 to Mn is a negative (−) voltage.

The resistors R_{G1} to R_{Gn} and the resistor R_{GC} may be gate resistors, and may prevent RF signals from leaking to the gate terminals of the transistors M1 to Mn when the transistors M1 to Mn are turned on or turned off.

The body terminal of each transistor M1 to Mn may be connected to a first end of each resistor R_{B1} to R_{Bn}, and the respective second ends of each resistor R_{B1} to R_{Bn} may be connected to the common node N2. A first end of the resistor R_{BC} may be connected to the common node N2, and the bias control signal VB may be applied to the second end of the resistor R_{BC}.

The bias control signal VB may have a voltage of 0 V and a negative (−) voltage. When a turn-on voltage is applied to the gate terminals of the transistors M1 to Mn, the bias control signal VB is 0V (e.g., VSS in FIG. 1), and when the turn-off voltage is applied to the gate terminals of the transistors M1 to Mn, the bias control signal VB has a negative (−) voltage (e.g., VNEG in FIG. 1).

Each resistor R_{DS1} to R_{DSn} may be connected between the drain terminal of each transistor M1 to Mn and the source terminal of each transistor M1 to Mn. Each of the resistors R_{DS1} to R_{DSn} may maintain the same direct current (DC) voltage between the drain terminal and the source terminal of each transistor M1 to Mn when the transistors M1 to Mn are turned off.

The gate control signal VG and the body control signal VB may be generated by the switch control circuit (130 in FIG. 1). The switch control circuit 130 generates a gate control signal VG and a body control signal VB, and may respectively apply the gate control signal VG and the body control signal VB to gate terminals and body terminals of the transistors M1 to Mn.

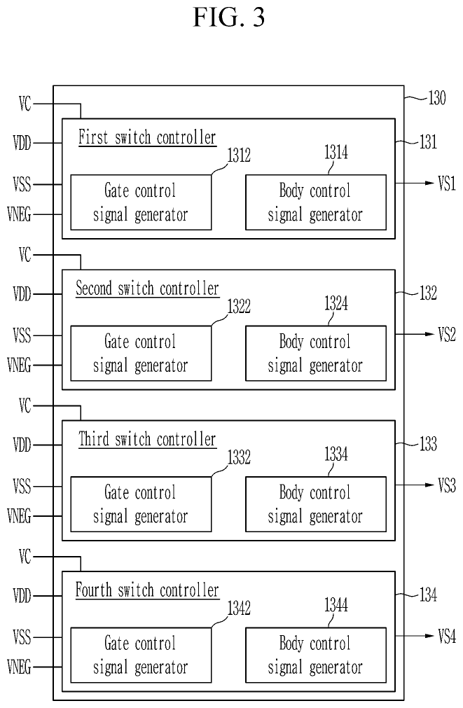

FIG. 3 is a schematic diagram of an example switch control circuit 130, in accordance with one or more embodiments.

Referring to FIG. 3, the switch control circuit 130 controls the switches constituting the RF switch 100.

When the RF switch 100 includes a series switch S1, a series switch S2, a shunt switch S3, and a shunt switch S4 as illustrated in FIG. 1, the switch control circuit 130 may include a first switch controller 131, a second switch controller 132, a third switch controller 133, and a fourth switch controller 134.

The first switch controller 131 may generate and output a switch control signal VS1 that controls the series switch S1. When the series switch S1 is configured as shown in FIG. 2, the first switch controller 131 generates a gate control signal VG and a body control signal VB according to the control signal VC as the switch control signal VS1. The first switch controller 131 may include a gate control signal generator 1312 and a body control signal generator 1314 that respectively generate a gate control signal VG and a body control signal VB, based on a positive voltage VDD, a negative voltage VNEG, and a ground voltage VSS.

The second switch controller 132 may generate and output a switch control signal VS2 that controls the series switch S2. When the series switch S2 is configured as shown in FIG. 2, the second switch controller 132 generates a gate control signal VG and a body control signal VB according to the control signal VC as the switch control signal VS2. The second switch controller 132 may include a gate control signal generator 1322 and a body control signal generator 1324 that respectively generate a gate control signal VG and a body control signal VB, based on a positive voltage VDD, a negative voltage VNEG, and a ground voltage VSS.

The third switch controller 133 may generate and output a switch control signal VS3 that controls the shunt switch S3. When the shunt switch S3 is configured as shown in FIG. 2, the third switch controller 133 generates a gate control signal VG and a body control signal VB according to the control signal VC as the switch control signal VS3. The third switch controller 133 may include a gate control signal generator 1332 and a body control signal generator 1334 that respectively generate a gate control signal VG and a body control signal VB, based on a positive voltage VDD, a negative voltage VNEG, and a ground voltage VSS.

The fourth switch controller 134 may generate and output a switch control signal VS4 that controls the shunt switch S4. When the shunt switch S4 is configured as shown in FIG. 2, the fourth switch controller 134 generates a gate control signal VG and a body control signal VB according to the control signal VC as the switch control signal VS4. The fourth switch controller 134 may include a gate control signal generator 1342 and a body control signal generator 1344 that respectively generate a gate control signal VG and a body control signal VB, based on a positive voltage VDD, a negative voltage VNEG, and a ground voltage VSS.

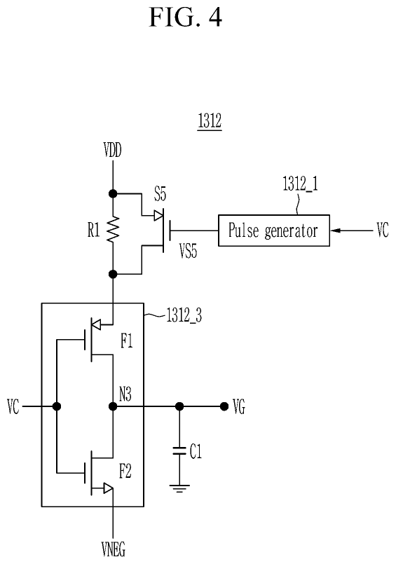

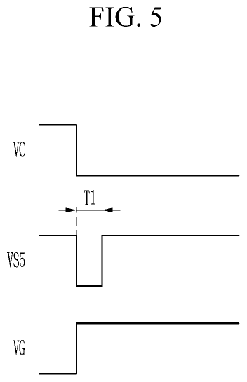

FIG. 4 is a circuit diagram illustrating an example gate control signal generator 1312 shown in FIG. 3.

Although the gate control signal generator 1312 is shown in FIG. 4, the gate control signal generators 1322, 1332, and 1342 may also be configured similarly or identically to the gate control signal generator 1312.

The gate control signal generator 1312 may include a transistor F1, a transistor F2, a resistor R1, a capacitor C1, a transistor S5, and a pulse generator 1312_1.

In a non-limited example, the transistor F1 may be a P-type FET, and the transistor F2 may be an N-type FET. A positive voltage VDD supplied from an external power supply may be applied to a source terminal of the transistor F1 through a resistor R1 or through the transistor S5, and a drain terminal of the transistor F1 may be connected to the node N3. The node N3 may be an output terminal of the gate control signal generator 1312.

A negative voltage VNEG is applied to a source terminal of the transistor F2, and a drain terminal of the transistor F2 may be connected to the node N3. The control signal VC may be input to the gate terminal of the transistor F1 and the gate terminal of the transistor F2. The negative voltage VNEG may be generated from an external power supply which supplies the positive voltage VDD through a charge pump circuit. At this time, the charge pump circuit may generate a negative voltage VNEG, and may remove noise from an external power supply.

These transistors F1 and F2 may perform the operation of the inverter 1312_3. When the control signal VC is at a high level (that is, a positive voltage), the transistor F2 is turned on, and the gate control signal VG becomes a negative voltage VNEG. Furthermore, when the control signal VC is at a low level (that is, a negative voltage or 0 V), the transistor F1 is turned on and the gate control signal VG becomes the positive voltage VDD.

In a non-limited example, the transistor S5 may be a P-type FET. A source terminal of the transistor S5 may be connected to a first end of the resistor R1 and a power supply which supplies a positive voltage VDD. The drain terminal of the transistor S5 may be connected to the second terminal of the resistor R1 and the source terminal of the transistor F1. That is, the transistor S5 may be connected in parallel with the resistor R1. Accordingly, when the transistor S5 is turned on, the positive voltage VDD may be output through the transistor S5 without being output through the resistor R1.

The transistor S5 may be turned on or turned off according to the control signal VS5 output from the pulse generator 1312_1. Since the transistor S5 may be P-type FET, the transistor S5 may be turned on when the control signal VS5 is at a low level (e.g., 0 V) and may be turned off when the control signal VS5 is at a high level (e.g., a positive voltage).

The pulse generator 1312_1 may generate a control signal VS5 based on the control signal VC. The pulse generator 1312_1 may generate the control signal VS5 which has a first level during a predetermined time at a trigger edge (e.g., a rising edge or a falling edge) of the control signal VC. In an example, the control signal VS5 may be generated to turn on the transistor S5 during a predetermined time at the falling edge of the control signal VC from a high level to a low level. When the control signal VC is at a low level, the transistor F1 is turned on, and the transistor S5 is turned on during a predetermined time from the falling edge of the control signal VC, thus a positive voltage VDD supplied from an external power supply may be output as a gate control signal VG through the transistor S5.

The capacitor C1 may be connected between node N3 and ground. The capacitor C1 may be used to remove high-frequency noise of the RF signal by absorbing a high-frequency signal and passing a low-frequency signal.

In this example, the resistor R1 and the capacitor C1 may operate as a resistor-capacitor (RC) filter. The cut-off frequency of the RC filter may be determined as in Equation 1 below.

$${f}_{c} = \frac{1}{2 π RC} \qquad Equation 1$$

In an example, f_{c} is the cut-off frequency, R may represent the resistance value of the resistor R1, and C may represent the capacitance value of the capacitor C1.

Therefore, by setting the resistance value of the resistor R1 and the capacitance value of the capacitor C1 according to the noise of the external power supply supplying the positive voltage VDD, it is possible to remove (block) the desired frequency band, that is, power supply noise.

Additionally, a resistor R1 that performs the operation of an RC filter is connected between an external power supply that supplies a positive voltage VDD and the source terminal of the transistor F1, and a transistor S5 is connected in parallel to the resistor R1. Then, the switching time of the gate control signal VG may be quickly adjusted by preventing the positive voltage VDD supplied from the external power supply from passing through the resistor R1 for a predetermined time from the falling edge of the control signal VC.

Additionally, when a negative voltage VNEG is output as the gate control signal VG by turning on the transistor F2, it is possible to prevent a voltage drop (IR drop) caused by a resistor.

FIG. 5 illustrates operation timing of the gate control signal generator 1312 shown in FIG. 4.

Referring to FIG. 5, when the control signal VC has a high level, the transistor F2 is turned on and a negative voltage VNEG is output as the gate control signal VG.

In an example, the pulse generator 1312_1 may generate the control signal VS5 having a low level during a predetermined period T1 at a trigger edge when the control signal VC changes from a high level to a low level.

When the control signal VC has a low level, the transistor F1 may be turned on. At this time, since the transistor S5 is turned on during a predetermined period T1 in which the control signal VS5 has a low level among the period in which the control signal VC is at a low level, the positive voltage VDD may be output as the gate control signal VG through the transistor S5 and the transistor F1.

When the predetermined period T1 passes among the period in which the control signal VC is at the low level, the control signal VS5 becomes the high level, so the transistor S5 may be turned off. When the transistor S5 is turned off, the positive voltage VDD may be output as the gate control signal VG through the resistor R1 and the transistor F1. That is, even when the transistor S5 is turned off, the gate control signal VG may maintain a positive voltage VDD.

In this manner, when the positive voltage VDD is output as the gate control signal VG, noise of the external power supplying the positive voltage VDD may be removed through the resistor R1 and the capacitor C1. Additionally, since the positive voltage VDD is output as the gate control signal VG through the transistor S5 for a predetermined time T1 at the trigger edge when the control signal VC changes from the high level to the low level, regardless of the resistance value of the resistor R1, the switching time of the gate control signal VG can be quickly adjusted.

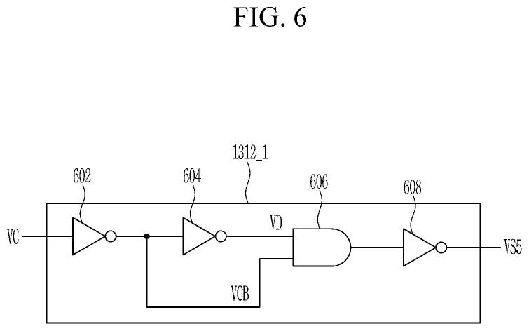

FIG. 6 is a circuit diagram illustrating an example of the pulse generator 1312_1 shown in FIG. 4.

Referring to FIG. 6, the pulse generator 1312_1 may include an inverter 602, an inverter 604, and an AND gate 606 that is a conjunction element. The pulse generator 1312_1 may further include an inverter 608 depending on whether the transistor S5 shown in FIG. 4 is an N-type FET or a P-type FET. In an example, the pulse generator 1312_1 may further include an inverter 608 when the transistor S5 is a P-type FET.

A control signal VC may be input to an input terminal of the inverter 602, and an output terminal of the inverter 602 may be connected to an input terminal of the inverter 604. The output terminal of inverter 604 can be connected to one of the two input terminals of the AND gate 606, and the output terminal of inverter 602 can be connected to the other input terminal of the two input terminals of the AND gate 606.

The AND gate 606 may output a signal obtained by performing an AND operation on signals input to two input terminals. An output signal of the AND gate 606 may be a control signal VS5.

The inverter 602 may output a control signal VCB obtained by delaying the control signal VC by a set time. The inverter 604 may output a control signal VD obtained by delaying the control signal VCB by a set time. That is, the control signal VCB may be a delayed signal as the control signal VC passes through the inverter 602, and the control signal VD may be a delayed signal as the control signal VC passes through the inverter 602 and the inverter. Therefore, when the control signal VC changes from the high level to the low level, the control signal VCB may be changed from the high level to the low level after being delayed by the delay time of the inverter 602, and the control signal VD may be changed from the high level to the low level after being delayed by the sum of the delay time of the inverter 602 and the delay time of the inverter 604. Since the control signal VS5 is generated by performing an AND operation on the control signal VCB and the control signal VD by the AND gate 606, the control signal VS5 may have a high level during a time corresponding to the delay time of the inverter 602.

In this example, since the transistor S5 is a P-type FET in FIG. 4, the pulse generator 1312_1 may further include an inverter 608 connected to an output terminal of the AND gate 606. The inverter 608 may invert the output signal of the AND gate 606, in which case the output signal of the inverter 608 becomes the control signal VS5.

In an example, in FIG. 4, if the transistor S5 is an N-type FET, the inverter 608 may be omitted, and the control signal VS5 may be an output signal of the AND gate 606.

The pulse generator 1312_1 shown in FIG. 6 is only an example and may be configured in various forms.

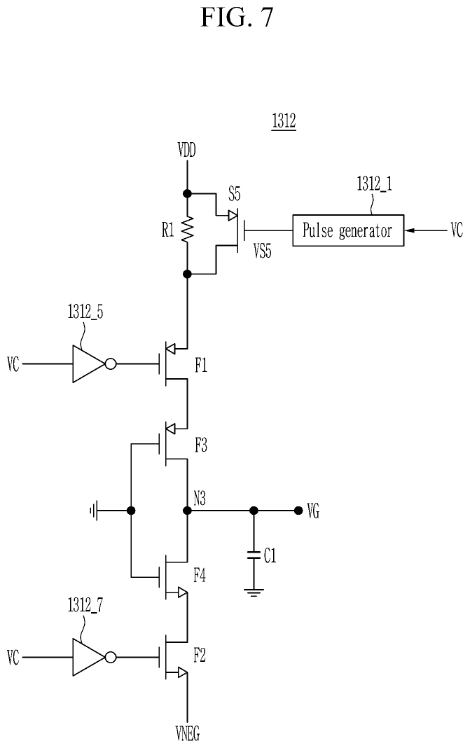

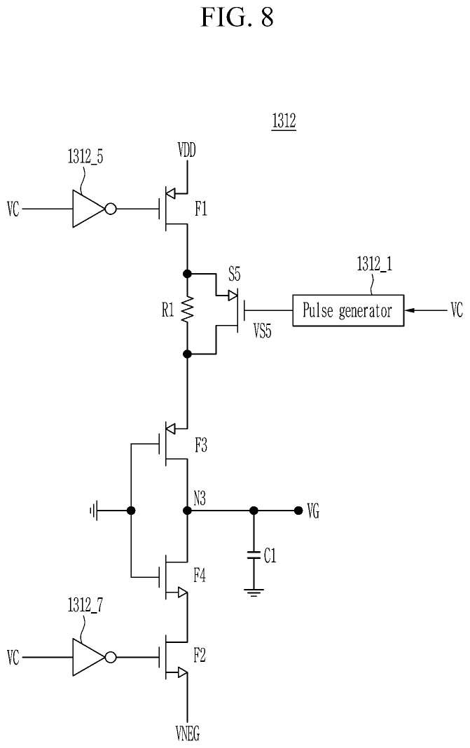

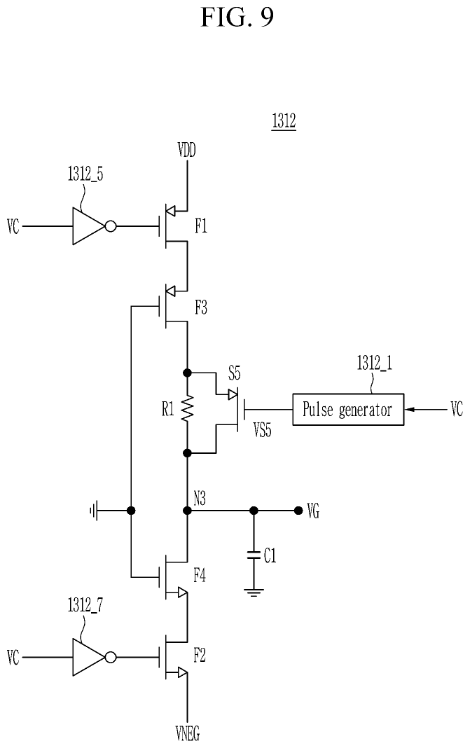

FIG. 7 to FIG. 9 are circuit diagrams illustrating another example of the gate control signal generator 1312 shown in FIG. 3.

Referring to FIG. 7, the gate control signal generator 1312 may further include at least one transistor F3 connected between the transistor F1 and the node N3 and at least one transistor F4 connected between the transistor F2 and the node N3.

In a non-limited example, the transistor F3 may be the same type of FET as the transistor F1, and the transistor F4 may be the same type of FET as the transistor F2.

The source terminal of the transistor F3 may be connected to the drain terminal of the transistor F1, and the drain terminal of the transistor F3 may be connected to the node N3. Additionally, the source terminal of the transistor F4 may be connected to the drain terminal of the transistor F2, and the drain terminal of the transistor F4 may be connected to the node N3. The gate terminal of the transistor F3 and the gate terminal of the transistor F4 may be connected to ground, the control signal VC may be applied to the gate terminal of the transistor F1 through the inverter 1312_5, and the control signal VC may be applied to the gate terminal of the transistor F2 through the inverter 1312_7.

When the control signal VC is at a high level, the transistor F1 may be turned on and the transistor F2 may be turned off. When the transistor F1 is turned on, the voltage difference between the gate terminal and the source terminal of the transistor F3 becomes a negative voltage, so the P-type transistor F3 is turned on and a positive voltage may be output as the gate control signal VG.

In an example, when the control signal VC is at a low level, the transistor F1 may be turned off and the transistor F2 may be turned on. When the transistor F2 is turned on, the voltage difference between the gate terminal and the source terminal of the transistor F4 becomes a positive voltage, so the N-type transistor F4 is turned on and a negative voltage VNEG may be output as the gate control signal VG.

The pulse generator 1312_1 of the gate control signal generator 1312 generates a control signal VS5 that turns on the transistor S5 during a predetermined time at the rising edge of the control signal VC from a low level to a high level. By doing this, when the transistors F1 and F3 are turned on and the positive voltage VDD is output as the gate control signal VG, noise of the power supply may be removed. Furthermore, since the positive voltage VDD may be output through the transistor S5 during a predetermined period, the switching time of the gate control signal VG may be quickly adjusted. Additionally, when the transistors F2 and F4 are turned on and the negative voltage VNEG is output as the gate control signal VG, a voltage drop that may occur due to the resistor R1 may be prevented. Additionally, as shown in FIG. 3, instead of one transistor F1, the transistor F1 and the transistor F3 may be stacked, and instead of one transistor F2, the transistor F2 and the transistor F4 may be stacked. In this example, the breakdown voltage of the gate control signal generator 1312 may be improved.

Referring to FIG. 8, unlike FIG. 7, a transistor F1 may be connected between a power supply which supplies a positive voltage VDD and a resistor R1. That is, the resistor R1 may be connected between the drain terminal of the transistor F1 and the source terminal of the transistor F3. Even if connected in this manner, the operation and effect of the gate control signal generator 1312 may be the same as that of FIG. 7.

Next, referring to FIG. 9, unlike FIG. 7, stacked transistors F1 and F3 may be connected between a power supply which supplies a positive voltage VDD and a resistor R1. That is, the resistor R1 may be connected between the drain terminal of the transistor F4 and the node N3. Even if connected in this manner, the operation and effect of the gate control signal generator 1312 may be the same as that of FIG. 7.

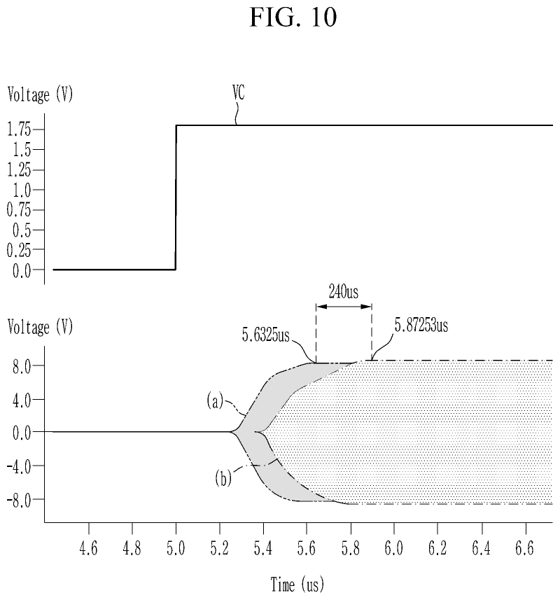

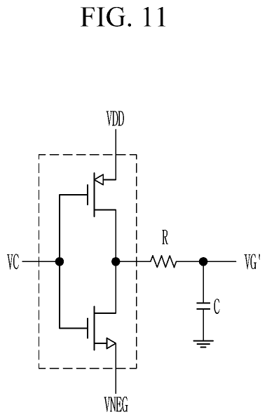

FIG. 10 is a diagram showing simulation results of the switching time of the gate control signal VG, in accordance with one or more embodiments, and FIG. 11 is a diagram showing an example of a switch control circuit in a comparative example.

In FIG. 10, (a) illustrates the switching time of the gate control signal VG generated by the gate control signal generator 1312 shown in FIG. 4, and (b) illustrates the switching time of the gate control signal VG′ generated by the switch control circuit of the comparative example in which the resistor R of the RC filter is connected to the output terminal, as shown in FIG. 11.

Referring to FIG. 10, the gate control signal generator 1312 shown in FIG. 4 turns on the transistor S5 during a predetermined period from the time when the transistor F1 is turned on among the period in which the transistor F1 is turned on, so that the switching time of the control signal VG may be adjusted faster than the switching time of the gate control signal VG′ generated by the switch control circuit of the comparative example.

According to at least one of the embodiments, noise of an external power supply may be removed using a resistor-capacitor (RC) filter.

Additionally, by connecting a transistor in parallel to a resistor constituting the RC filter and controlling the transistor, the switching time of the control signal controlling the RF switch can be quickly adjusted.

While this disclosure includes specific examples, it will be apparent to one of ordinary skill in the art, after an understanding of the disclosure of this application, that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A switch control circuit configured to transmit a turn-on voltage and a turn-off voltage through an output terminal to control a switch, the switch control circuit comprising:
a first transistor configured to be turned on in response to a first control signal being at a first voltage level, and output the turn-on voltage;
a second transistor configured to be turned on in response to the first control signal being at a second voltage level, and output the turn-off voltage;
a resistor connected between a power supply and the output terminal; and
a capacitor connected between the output terminal and a ground,
wherein the power supply is configured to supply the turn-on voltage of the switch.

2. The switch control circuit of claim 1, further comprising:
a third transistor connected in parallel with the resistor and configured to be turned on for a first period from a first time point when the first control signal is changed from the second voltage level to the first voltage level.

3. The switch control circuit of claim 2, further comprising:
a pulse generator configured to generate a second control signal to turn on the third transistor during the first period from the first time point.

4. The switch control circuit of claim 3, wherein the first period is a portion of a period in which the first transistor is turned on.

5. The switch control circuit of claim 3, wherein the pulse generator comprises:
a first inverter configured to receive the first control signal, and delay and output the first control signal by a set time;
a second inverter configured to delay and output the output signal of the first inverter by a set time; and
a logic element configured to generate the second control signal based on an output signal of the first inverter and an output signal of the second inverter.

6. The switch control circuit of claim 5, wherein the logic element is an AND gate.

7. The switch control circuit of claim 2, further comprising:
a fourth transistor connected between the first transistor and the output terminal, wherein the fourth transistor has a control terminal connected to a ground terminal, and is configured to be turned on when the first transistor is turned on; and
a fifth transistor connected between the second transistor and the output terminal, wherein the fifth transistor has a control terminal connected to the ground terminal, and is configured to be turned on when the second transistor is turned on.

8. The switch control circuit of claim 7, wherein:
the resistor is connected to any one of between the power supply and the first transistor, between the first transistor and the fourth transistor, and between the fourth transistor and the output terminal.

9. A radio frequency (RF) switch, comprising:
a switch connected between a first port and a second port; and
a switch control circuit configured to output a turn-on voltage corresponding to a first voltage level of a first control signal to the switch through an output terminal of the switch control circuit, and configured to output a turn-off voltage corresponding to a second voltage level of the first control signal to the switch through the output terminal of the switch control circuit,
wherein the switch control circuit comprises:
a first transistor configured to provide the turn-on voltage to the output terminal;
a second transistor configured to provide the turn-off voltage to the output terminal;
a resistor connected between a power supply which transmits the turn-on voltage and the output terminal; and
a capacitor connected between the output terminal and a ground.

10. The RF switch of claim 9, wherein:
the switch control circuit further comprises a third transistor connected in parallel with the resistor, and configured to be turned on during a second period from a first time point when the first control signal is changed from the second voltage level to the first voltage level among a first period when the first transistor is turned on.

11. The RF switch of claim 10, wherein:
the switch control circuit further comprises a pulse generator configured to generate a second control signal to turn on the third transistor during the second period from the first time point, and output the second control signal to a control terminal of the third transistor.

12. The RF switch of claim 11, wherein the pulse generator is configured to generate the second control signal based on the first control signal.

13. The RF switch of claim 10, wherein:
the switch control circuit further comprises:
a fourth transistor connected between the first transistor and the output terminal, wherein the fourth transistor has a control terminal connected to the ground, and is configured to be turned on when the first transistor is turned on; and
a fifth transistor connected between the second transistor and the output terminal, wherein the fifth transistor has a control terminal connected to the ground, and is configured to be turned on when the second transistor is turned on.

14. The RF switch of claim 13, wherein:
the resistor is connected to any one of between the power supply and the first transistor, between the first transistor and the fourth transistor, and between the fourth transistor and the output terminal.

15. A radio frequency (RF) switch, comprising:
a switch control circuit, comprising a gate control signal generator configured to generate a gate control signal;
wherein the gate control signal generator comprises:
a first transistor connected between a first power supply and an output terminal, and configured to receive a positive voltage from the power supply;
a second transistor connected between the output terminal and a second power supply, and configured to receive a negative voltage;
a resistor connected between the power supply and the first transistor, and
a third transistor connected in parallel with the resistor, and configured to be turned on or turned off based on a control signal output from a pulse generator.

16. The RF switch of claim 15, wherein a first end of the resistor is connected to a source terminal of the third transistor, and a second end of the resistor is connected to a drain terminal of the third transistor.

17. The RF switch of claim 15, wherein the third transistor is turned on when the control signal is at a low voltage level, and is turned off when the control signal is at a high voltage level.
